(19) United States
(12) Patent Application Publication
(10) Pub. No.: US 2007/0007246 A1
(43) Pub. Date: Jan. 11, 2007

(54) Manufacture of semiconductor device with CMP

(75) Inventor: Naoki Idani, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/264,240

(22) Filed: Nov. 2, 2005

(30) Foreign Application Priority Data
Jul. 11, 2005 (JP) 2005-202061
Jul. 11, 2005 (JP) 2005-202060

(51) Int. Cl. C03C 15/00; B44C 1/22; H01L 21/461

(52) U.S. Cl. 216/88; 438/692; 216/89

(57) ABSTRACT

A manufacture method for a semiconductor device, includes the steps of: in CMP for forming STI, (a) polishing the surface of a film formed on a semiconductor substrate until the surface of the film is planarized, by using first abrasive containing cerium dioxide abrasive grains and additive of interfacial active agent; (b) after the step (a), polishing the surface of the film is polished by using second abrasive having a physical polishing function; and (c) after the step (b), polishing the surface of the film by using third abrasive containing cerium dioxide abrasive grains, additive of interfacial active agent, and diluent. The manufacture method further includes the steps of: (p) forming wirings above the semiconductor substrate; (q) depositing a first insulating film by HDP CVD, the first insulating film burying the wirings; (r) depositing a second insulating film above the first insulating film by a deposition method different from HDP-CVD; and (s) planarizing the second insulating film by chemical mechanical polishing using abrasive containing cerium dioxide abrasive grains. It is possible to solve an issue of a left film after polishing newly found from a large size substrate and to suppress a distribution of thicknesses of an interlayer insulating film at a wafer level.

### CROSS REFERENCE TO RELATED APPLICATION

This application is based on and claims priority of Japanese Patent Applications No. 2005-202060 & 2005-202061, both filed on Jul. 11, 2005, the entire contents of which are incorporated herein by reference.

### BACKGROUND OF THE INVENTION

A) Field of the Invention

The present invention relates to a semiconductor device manufacture method and a semiconductor device manufactured by the method, and more particularly to a semiconductor device manufacture method including a chemical mechanical polishing (CMP) process of planarizing a deposited film and a semiconductor device manufactured by the method.

B) Description of the Related Art

Local oxidation of silicon (LOCOS) is widely used as the technique of forming an isolation region defining active regions, in which a silicon substrate is selectively oxidized by using a silicon nitride mask formed on a buffer oxide film on the silicon substrate. While the isolation region of silicon oxide is formed by LOCOS, the silicon substrate is oxidized also under the peripheral edge of the silicon nitride mask so that bird's beaks are formed and the area of active regions is reduced. The isolation region of silicon oxide swells over the surface of the silicon substrate and forms large steps. LOCOS has difficulties in further miniaturization and higher integration of semiconductor devices.

Shallow trench isolation (STI) is used as an alternative of the LOCOS technique.

In forming STI, the surface of a silicon substrate is thermally oxidized to form a buffer silicon oxide film, a silicon nitride film is deposited on the buffer silicon oxide film, an opening corresponding to STI is formed through the silicon nitride film by photolithography and etching, and a trench is formed in the silicon substrate. The silicon nitride film functions as an etching mask as well as a stopper for CMP.

The silicon surface exposed in the trench is thermally oxidized to form a silicon oxide film liner, and a silicon nitride film is deposited to form a silicon nitride film liner. Thereafter, an insulating film, e.g., an undoped silicate glass (USG) film, is buried in the trench. In order to bury an USG film in a fine trench, high density plasma (HDP) chemical vapor deposition (CVD) has been used. The USG film deposited outside the trench is removed by CMP. After CMP, the exposed silicon nitride film is etched by hot phosphoric acid or the like, and the buffer silicon oxide film is etched by dilute hydrofluoric acid or the like.

In CMP, abrasive is used which contains abrasive grains made of, e.g., silica, additive made of KOH, and water. It is desired that abrasive provides a fast polishing rate relative to silicon oxide and a polishing rate as slow as possible relative to silicon nitride (silicon nitride functions as a polishing stopper) and that abrasive can planarize the polished surface to a large degree. The abrasive which contains abrasive grains made of silica and additive made of KOH provides a polishing rate not so fast relative to silicon oxide and shows a polishing rate of about 300 nm/min even after the silicon nitride stopper is exposed. Although the polished surface is planarized to a certain degree, some steps are left. Requirements for desired abrasive are a faster polishing rate relative to silicon oxide, a high selectivity, and a good planarized surface after polishing.

Abrasive satisfying these requirements has been proposed which contains abrasive grains made of cerium oxide (ceria, cerium dioxide CeO₂) and additive made of polyacrylate ammonium salt and the like. Abrasive mixing cerium oxide and water has too fast a polishing rate and a low step relaxing function. As polyacrylate ammonium salt is added, the polishing rate can be controlled to have a proper value which suppresses polishing in a concave area and improve a planarizing function, so that an auto stop function is presented when the polished surface is planarized. Abrasive containing cerium oxide and additive has an excellent performance of planarizing an irregular surface.

For chemical mechanical polishing using cerium oxide, for example, refer to JP-A-2001-009702, JP-A-2001-085373 and JP-A-2000-248263, which are incorporated herein by reference. Polishing until an irregular surface is removed is called main polishing. As the technique of detecting a polishing end when an irregular surface of the polished surface is removed, a technique of detecting a temperature and a rotation torque of a polished surface has also been proposed in JP-A-HEI-11-104955.

A CMP polishing system is equipped with a rotatable polishing table having polishing surfaces, rotatable polishing heads for holding substrates and a plurality of nozzles for supplying abrasive and water. While a depressing force is applied to depress the polishing head against the polishing table, polishing is performed while the polishing head and polishing table are rotated and abrasive is supplied. For general knowledge on a CMP polishing system, for example, refer to JP-A-2001-338902 and JP-A-2002-083787, which are herein incorporated by reference.

A method has also been proposed in which CMP is divided into two stages and two stages of CMP are performed under different conditions to achieve high planarization. For example, main polishing is performed using a first polishing pad while abrasive is supplied, thereafter the supply of abrasive is stopped, and finish polishing is performed using a second polishing pad harder than the first polishing pad while water is supplied, to thereby prevent dishing. For example, refer to JP-A-2004-296591.

CMP is used for forming STI and other cases. Concave portions such as holes and trenches reaching an underlying conductor in addition to STI are formed in an insulating film, a conductive film burying the concave portions is formed and an unnecessary conductive film on a substrate surface is removed to form plugs and damascene wirings. In removing this unnecessary conductive film, CMP is used. Wirings and the like including gate electrodes are formed on an insulating film, another insulating film is deposited covering the wirings, and the surface of the other insulating film is planarized. In planarizing the surface, CMP is used. By planarizing the surface, it becomes possible to improve a precision of a photolithography process with only a shallow depth of focus and the uniformity of an etching process.

In forming a gate electrode of a MOS transistor, a silicon oxide film is formed on the surface of active regions of a silicon substrate to form a gate insulating film by doping nitrogen if necessary. On the gate insulating film, a polysilicon film is deposited and patterned in a gate electrode shape. After ion implantation is performed for forming extension regions of source/drain regions, side wall spacers are formed and then ion implantation is performed for forming high impurity concentration regions of the source/drain regions. After a silicidation process is performed if necessary, a phosphosilicate glass (PSG) film which is a silicon oxide film containing phosphorus is deposited to form an interlayer insulating film covering gate electrodes.

The interlayer insulating film covering gate electrodes has an irregular surface. In order to remove the irregular surface, the interlayer insulating film is planarized by CMP. The deposited interlayer insulating film has a marginal thickness which is polished by CMP. After planarization, contact holes for source/drain regions and the like are formed by etching, and conductive plugs of polysilicon, tungsten or the like are buried in the contact holes. An unnecessary conductive film on the interlayer insulating film is removed by CMP.

Further miniaturization and higher integration are progressing for semiconductor integrated circuit devices. The gate length of a MOS transistor is shortened from 90 nm to 65 nm. The lowermost wiring layer of an integrated circuit device is a gate wiring layer. A distance between gate wirings is made narrower as miniaturization progresses and wirings are made dense. After gate wirings are formed, a PSG film is deposited to form an interlayer insulating film which buries the gate wirings. Conventionally, a PSG film has been deposited by plasma enhanced (PE) CVD with an RF power being applied across opposing electrodes. However, as the distance between gates is shortened, the burying performance becomes insufficient. As a PSG film is buried in the narrow gap between gates, voids are formed in the PSG film in some cases. In order to fill the narrow gap with the PSG film, high density plasma (HDP) CVD with an RF power being applied to an induction coupled coil is used in place of PE-CVD.

### SUMMARY OF THE INVENTION

An object of the present invention is to solve the issue newly found by the advent of a large substrate.

Another object of the present invention is to provide a semiconductor device manufacture method including a polishing process excellent in planarization of a polished surface.

Still another object of the present invention is to provide a manufacture method for a semiconductor device excellent in uniformity of the thickness of an interlayer insulating film at a wafer level.

Still another object of the present invention is to provide a semiconductor device manufacture method including an efficient CMP process.

Still another object of the present invention is to provide a semiconductor device having a novel structure.

According to one aspect of the present invention, there is provided a manufacture method for a semiconductor device, comprising steps of: (a) while first abrasive is supplied to a polishing table provided with a polishing pad, polishing a surface of a film formed on a semiconductor substrate supported by a polishing head, by using the polishing pad, until the surface of the film is planarized, the first abrasive containing cerium dioxide abrasive grains and additive of interfacial active agent; (b) after the step (a), polishing the surface of the film by using second abrasive having a physical polishing function; and (c) after the step (b), polishing the surface of the film by using third abrasive containing cerium dioxide abrasive grains, additive of interfacial active agent, and diluent.

According to another aspect of the present invention, there is provided a manufacture method for a semiconductor device, comprising steps of: (a) forming wirings above a semiconductor substrate; (b) after the step (a), depositing a first insulating film by high density plasma (HDP) chemical vapor deposition (CVD), the first insulating film burying the wirings; (c) after the step (b), depositing a second insulating film above the first insulating film by a deposition method different from HDP-CVD; and (d) after the step (c), planarizing the second insulating film by chemical mechanical polishing using abrasive containing cerium dioxide abrasive grains.

According to another aspect of the present invention, there is provided a semiconductor device comprising: a silicon substrate; a shallow trench isolation (STI) formed in the silicon substrate and including a trench defining active regions and an undoped silicate glass film buried in the trench; a gate insulating film formed on the active region; a gate insulating film formed above the gate insulating film; a lower insulating film of phosphosilicate glass (PSG) or borophosphosilicate glass (BPSG) having an uneven surface and formed above the silicon substrate, the lower insulating film covering the gate electrode; and an upper insulating film of TEOS silicon oxide formed above the lower insulating film and having a planarized surface.

The physical polishing process following CMP using the first abrasive polishes the surface of a film on the semiconductor substrate so that residues of the first abrasive are removed. Thereafter, another chemical mechanical polishing is performed to obtain a highly planarized surface in the whole semiconductor surface area.

As the interlayer insulating film is deposited by HDP-CVD, the thickness of the interlayer insulating film has a variation. However, a combination of HDP-CVD and another deposition method can form an interlayer insulating film having a uniform thickness.

### BRIEF DESCRIPTION OF THE DRAWINGS

FIG. 1A is a plan view of a polishing system, FIG. 1B is a partially broken side view of one polishing table, FIG. 1C is a plan view of one polishing table, and FIG. 1D is a partially broken side view of a grinder unit.

FIGS. 2A to 2D is schematic cross sectional views showing the states of a film to be polished during a polishing process executed for preliminary studies, and FIG. 2E is a plan view of a wafer having a left oxide film after a polishing process.

FIGS. 3A to 3E are cross sectional views of a semiconductor wafer illustrating a polishing process according to an embodiment.

FIG. 4 is a graph showing a change in torque during a polishing process.

FIGS. 5A and 5B are a plan view and a cross sectional view of a semiconductor device.

FIG. 6A is a cross sectional view showing the structure of a sample used by preliminary experiments, and FIG. 6B is a graph showing thickness distributions of three types of silicon oxide films OX deposited on substrates SUB.

FIG. 7A is a graph showing polishing rates of three types of silicon oxide films polished with the same kind of ceria slurry, and FIG. 7B is a graph showing polishing rates of HDP-PSG films polished with ceria slurry containing polyacrylate ammonium salts having different concentrations.

FIGS. 8A to 8C are cross sectional views of a semiconductor wafer illustrating a semiconductor device manufacture method according to another embodiment.

FIG. 9A is a graph showing the thickness distributions of interlayer insulating films, and FIG. 9B is a graph showing a change in film thickness variation relative to a ratio of a lower interlayer insulating film thickness to a wiring height.

FIG. 10A is a cross sectional view of a semiconductor wafer illustrating two steps of a polishing process, and FIG. 10B is a plan view of a polishing system showing the polishing nozzle layout.

FIG. 10C is a graph showing the numbers of scratches after first and second steps, and FIG. 10D is a graph showing film thickness distributions after polishing.

FIGS. 11A and 11B are cross sectional views of semiconductor wafers of two modifications of the embodiment.

FIGS. 12A and 12B are cross sectional views of a semiconductor wafer illustrating a DRAM manufacture method according to another embodiment.

### DESCRIPTION OF THE PREFERRED EMBODIMENTS

Abrasive containing cerium dioxide abrasive grains and additive made of interfacial active agent provides a high polishing rate relative to silicon oxide and an auto stop function of automatically stopping polishing when the polished surface becomes a planarized surface. If water is added to the abrasive to raise a water composition relative abrasive grains and additive, the auto stop function is suppressed, the polishing rate relative to silicon oxide having a planarized surface is recovered and a polishing selectivity relative to a silicon nitride film is maintained.

It can be considered therefore that the surface of an underlying film can be exposed in a good state by first planarizing a film to be polished with abrasive having a first composition containing cerium dioxide abrasive grains and additive made of interfacial active agent and thereafter polishing the film with abrasive having a second composition obtained by adding water to the abrasive having the first composition.

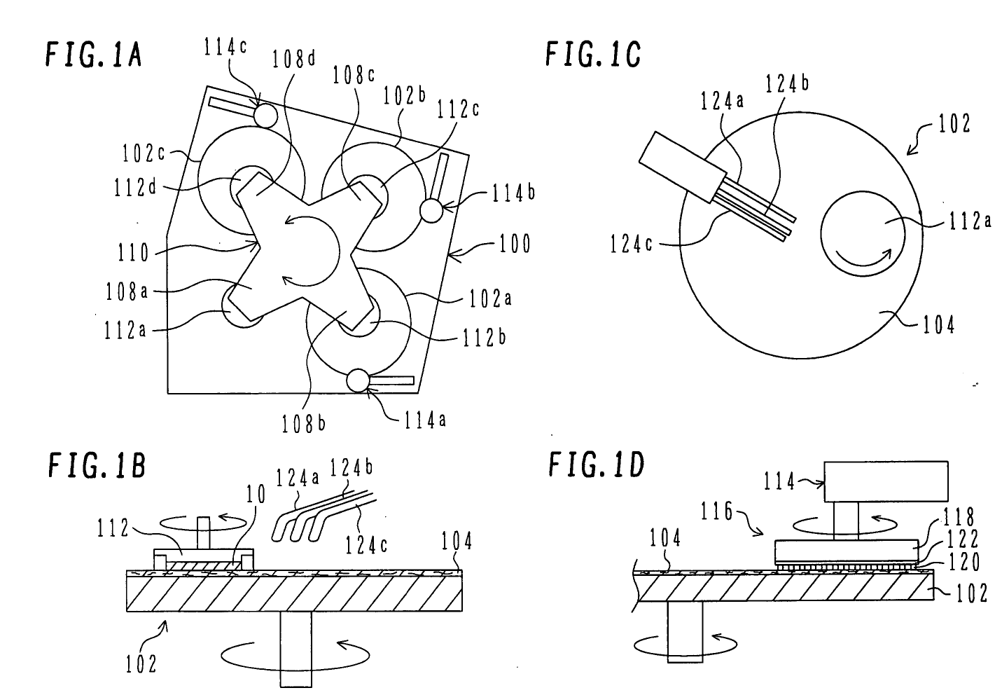

With reference to FIGS. 1A to 1D, description will be made on an example, of the structure of a polishing system used by experiments. FIG. 1A is a plan view of the polishing system, FIG. 1B is a partially broken side view of one polishing table, FIG. 1C is a plan view of one polishing table, and FIG. 1D is a partially broken side view of a grinder unit.

As shown in FIG. 1A, three polishing tables 102a, 102b and 102c are mounted on a base 100 of the polishing system. In order to distinguish among a plurality of similar members, suffixes a, b, c, d and the like are used. The suffixes a, b and the like are omitted if similar members are collectively designated. A carrousel 110 having four arms 108a to 108d are mounted on the base 100. The distal end of each arm 108 is coupled to a polishing head 112 for supporting an object to be polished. Three polishing heads are disposed on the polishing tables to polish objects at the same time. By using a remaining polishing head, an object to be polished is exchanged. The polishing tables 102, carrousel 110 and polishing heads 112 each can be rotated. Each polishing table 102 is provided with a grinder unit 114.

As shown in FIGS. 1B and 1C, a polishing pad 104 is mounted on each polishing table 102. For example, a polishing pad of Model Number IC1400 manufactured by Nitta Haas Incorporated is used. Polishing can be made without using the polishing pad. The polishing head 112 can support an object to be polished such as a semiconductor wafer 10 and can depress it against the polishing table 102. Nozzles 124a, 124b and 124c supply abrasive grains, diluent and the like to the polishing table. For example, three nozzles 124a, 124b and 124c supply abrasive containing ceria as abrasive grains, pure water as diluent or washing agent, and abrasive containing silica as abrasive grains. The nozzle 124c has not be used conventionally.

While the polishing table 102 and polishing head 112 are rotated, the polishing head 112 is depressed against the polishing table 102 and ceria based abrasive is supplied from the nozzle 124a to the polishing table so that an object to be polished supported by the polishing head can be subjected to main polishing. After the main polishing, ceria based abrasive and water are supplied to perform finish polishing for uniformity. When a plurality of polishing processes are performed, each process may be performed on the same polishing table or difference polishing tables.

As shown in FIG. 1D, the grinder unit 114 can grind the polishing pad 104 of each polishing table 102. The grinder unit 114 has a diamond disk 116 coupled to a rotary shaft of the unit. For example, the diamond disk 116 is formed by fixing diamond grains 120, several grains per 1 cm², having a grain diameter of about 150 μm to a stainless disk 118 by using a nickel plated layer 122. While the polishing table 102 is rotated, the diamond disk 116 is rotated and depressed against the polishing pad to grind the polishing pad. Grinding may be performed before or during polishing.

By using the polishing system shown in FIGS. 1A to 1D, a silicon oxide film for burying a shallow trench isolation (STI) was polished with abrasive containing ceria.

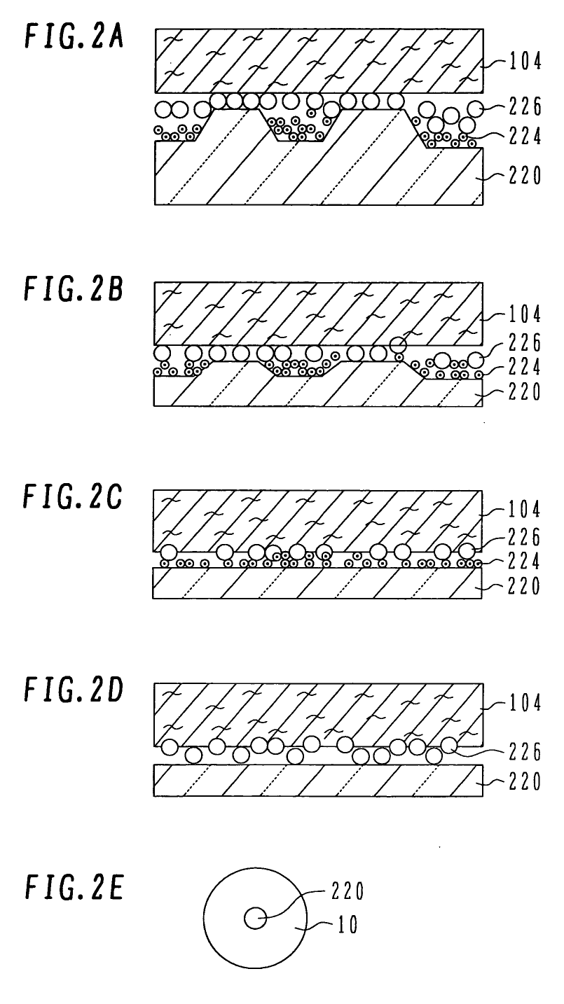

FIG. 2A is a schematic cross sectional view showing the state of a film before polishing. A silicon oxide film 220 to be polished has an irregular surface. Additive 224 made of interfacial active agent is attached to the surface of the film. The polishing pad 104 is depressed against the film 220 and rotated relative to the film. A high pressure is applied from the polishing pad 104 to a convex region of the film 220 so that additive 224 is moved away.

As shown in FIG. 2B, the convex region is polished with polishing abrasive grains 226. Polishing is hindered in a concave region because the additive 224 is attached to the surface of the concave region. In this manner, the convex region of the film 220 is selectively polished.

As shown in FIG. 2C, as the surface of the film 220 is planarized, the additive 224 made of interfacial active agent is attached to the whole surface of the film 220 so that the polishing rate is slowed greatly. At this time, supply of the abrasive is stopped and pure water is supplied.

As shown in FIG. 2D, it is anticipated that the additive 226 is removed in a short time because it is water soluble, while the polishing abrasive grains 224 are hard to be removed because it is not water soluble. Therefore, the film 220 is further polished with the polishing abrasive grains left between the polishing pad 104 and film 220. It is considered that the film can be polished uniformly and removed in the manner described above.

However, as shown in FIG. 2E, the silicon oxide film 220 on the semiconductor wafer 10 is not removed completely, but it is left in a central area of the wafer in some cases. A left oxide film in the wafer central area becomes conspicuous particularly for a wafer having a 300 mm diameter enlarged from a 200 mm diameter.

The present inventor has considered that the silicon oxide film is likely to be left in the wafer central area because additive attached to the wafer surface cannot be completely removed. It is considered that it is surest to physically polish a wafer surface in order to uniformly remove abrasive attached to the wafer surface. Physical polishing may be performed with abrasive containing silica or zirconia as polishing abrasive grains. In the following, embodiments of the present invention will be described.

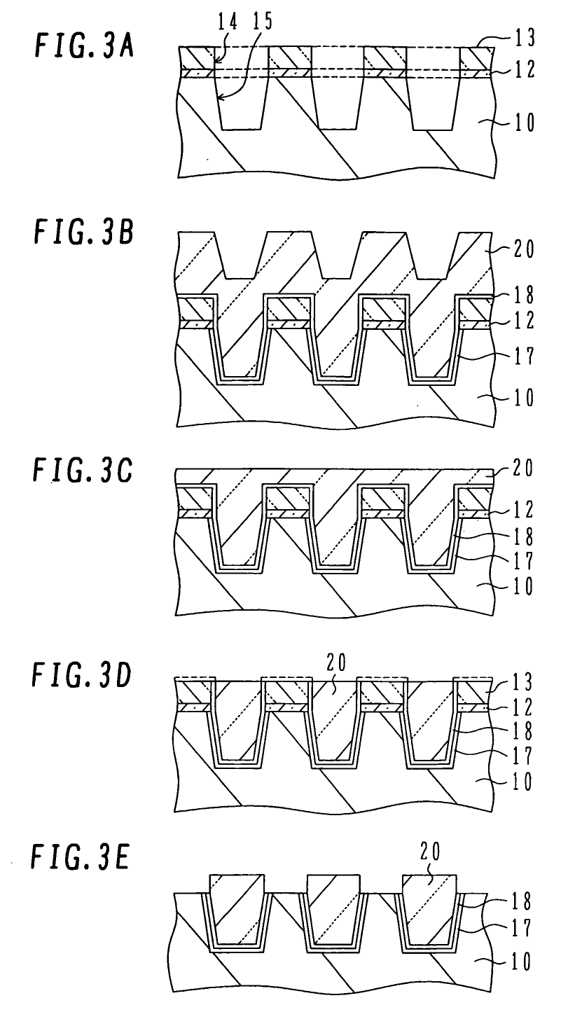

As shown in FIG. 3A, the surface of a silicon wafer semiconductor substrate 10 is thermally oxidized to form a silicon oxide film 12 having a thickness of about 10 nm. On the silicon oxide film 12, a silicon nitride film 13 having a thickness of about 100 nm is deposited by chemical vapor deposition (CVD). Openings 14 are formed through the silicon nitride film 13 and silicon oxide film 12 by photolithography and etching, the openings exposing surfaces of the semiconductor substrate 10. A resist pattern formed by photolithography may be removed at this stage. By using at least the silicon nitride film 13 having the openings as a mask, the semiconductor substrate 10 is anisotropically etched by reactive ion etching (RIE) to form a trench 15 having a depth of, e.g., about 300 nm as measured form the surface of the silicon nitride film 13. It is preferable to etch the substrate under the condition that the side wall of the trench is inclined.

As shown in FIG. 3B, the silicon surface exposed on the surface of the trench is thermally oxidized to form a silicon oxide film (liner) 17 having a thickness of, for example, about 1 to 5 nm. A silicon nitride film (liner) 18 is deposited by low pressure (LP) CVD to a thickness of, for example, about 2 to 8 nm, covering the surface of the silicon oxide film 17 and silicon nitride film 13. The thickness of about 1 to 5 nm of the silicon oxide film makes dilute hydrofluoric acid difficult to invade, and the thickness of about 2 to 8 nm of the silicon nitride film makes hot phosphoric acid difficult to invade. A silicon oxide film 20 having a thickness of, for example, about 450 nm is deposited on the semiconductor substrate with the silicon nitride film 18 by high density plasma (HDP) CVD. The trench 15 is filled with the silicon oxide film 20. The silicon oxide film 20 at a level higher than the surface of the silicon nitride film 13 (and silicon nitride film 18) is a film to be polished.

The semiconductor substrate 10 is supported by the polishing head 112 shown in FIGS. 1A to 1C, with the film 20 to be polished being directed downward. By rotating the carrousel 110, the polishing head 112 is disposed above the polishing table 102 with the polishing pad 104. While the polishing head 112 is rotated and lowered and abrasive containing ceria abrasive grains and additive is supplied from the nozzle 112a, the semiconductor substrate 10 is depressed against the polishing pad 104 of the polishing table 102.

As shown in FIG. 3C, main polishing is performed until surface irregularity is removed, to planarize the surface of the film 20. For example, the main polishing is performed under the following conditions:

a pressure of depressing the polishing head against the polishing pad: 100 to 500 g weight/cm², e.g., 210 g weight/cm²,

a rotation speed of the polishing head: 70 to 150 rpm, e.g., 142 rpm,

a rotation speed of the polishing table: 70 to 150 rpm, e.g., 140 rpm,

abrasive: abrasive containing ceria abrasive grains as polishing abrasive grains and polyacrylate ammonium salt as additive in pure water (e.g., Model Number MICROPLANAR STI2100 manufactured by Dupont Air Products NanoMaterials L.L.C.),

a supply amount of abrasive: 0.1 to 0.3 l/min, e.g., 0.15 l/min, and

a supply position of abrasive: a center of the polishing table (polishing pad).

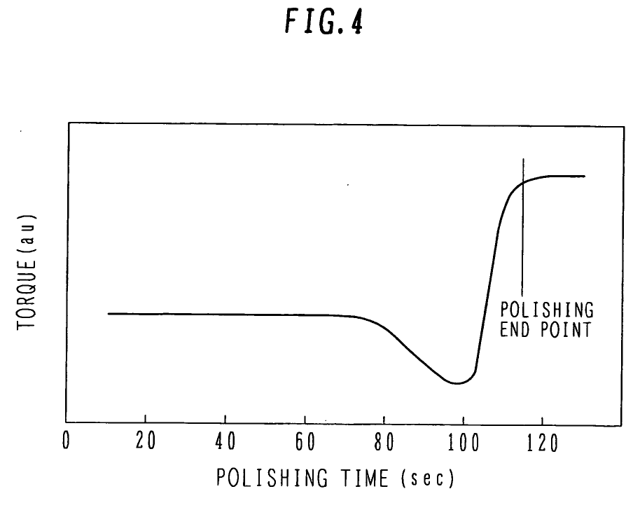

FIG. 4 is a graph showing a change in torque applied to the polishing table or polishing head during polishing. Generally a constant torque is applied for about 80 seconds from the polishing start, then the torque reduces once, increases greatly and saturates. The last increase of the torque is detected, and the time when the increase rate of the torque lowers more than a constant value is decided as a polishing end point. The torque can be monitored by measuring a drive voltage or current while the polishing head and table are rotated at constant rotation speeds. The main polishing end point may be detected by another method. For example, the torque itself may be monitored. If necessary, the polishing pad may be ground before or during main polishing.

The polishing pad may be ground under the following conditions:

a load applied to the polishing pad 104 from the diamond disk 116: 1300 to 4600 g weight, and

a rotation speed of the diamond disk 116: 70 to 120 rpm.

After the main polishing is completed and the surface of the silicon oxide film 20 is planarized, pure water is supplied from the nozzle 124b to wash out abrasive. There is a possibility that additive attached to the semiconductor substrate surface is not removed by this pure water wash only.

Next, preliminary polishing for finish polishing is performed. The preliminary polishing for finish polishing is performed by supplying abrasive of silica base to the central area of the polishing pad from, for example, the nozzle 124c. The abrasive of silica base may be abrasive of Model Number Semi-Sperse 25 manufactured by Cabot Microelectronics Corporation. While the polishing head 112 is rotated, the semiconductor substrate is depressed against the polishing pad 104 of the rotating polishing table 102. The preliminary polishing for finish polishing is performed, for example, under the following conditions:

a polishing pressure: 100 to 500 g weight/cm², e.g., 210 g weight/cm²,

a rotation speed of the polishing head: 70 to 150 rpm, e.g., 122 rpm,

a rotation speed of the polishing table: 70 to 150 rpm, e.g., 120 rpm,

a supply amount of abrasive: 0.05 to 0.3 l/min, e.g., 0.1 l/min, and

a polishing amount (time): a film thickness of 10 nm or thinner, e.g., 5 seconds.

The preliminary polishing for finish polishing removes additive possibly attached to the film by removing the film shallowly. It is preferable that the silicon nitride films 18 and 13 are not exposed.

After the preliminary polishing for finish polishing is completed, pure water is supplied from the nozzle 124b, for example, for about 10 seconds to wash out abrasive of silica base. If abrasive of silica base is left, selectivity of the finish polishing is degraded.

Thereafter, as shown in FIG. 3D, main polishing for finish polishing is performed by supplying abrasive of ceria base from the nozzle 124a and pure water from the nozzle 124b. For example, the abrasive of ceria base is supplied to the central area of the polishing pad and pure water is supplied to the area outside the central area. Supply positions are not limited to these areas. The polishing head and pad are both rotated.

The main polishing for finish polishing is performed, for example, under the following conditions:

a polishing pressure: 100 to 500 g weight/cm², e.g., 210 g weight/cm²,

a rotation speed of the polishing head: 70 to 150 rpm, e.g., 122 rpm,

a rotation speed of the polishing table: 70 to 150 rpm, e.g., 120 rpm,

a supply amount of abrasive: 0.05 to 0.3 l/min, e.g., 0.05 l/min,

a supply amount of pure water: 0.05 to 0.3 l/min, e.g., 0.15 l/min, and

a polishing amount (time): until the silicon nitride film is exposed, e.g., for about 60 seconds.

The conditions for the main polishing for finish polishing are not limited to those described above. The other conditions may be used if the silicon oxide on the silicon nitride film 13 (silicon nitride film 18) is removed and the silicon nitride film is exposed. The thin silicon nitride film 18 may be removed or left.

As shown in FIG. 3E, the silicon nitride film 13 (18) is etched with, for example, hot phosphoric acid and the silicon oxide film 12 is etched with, for example, dilute hydrofluoric acid. It is preferable not to etch the silicon oxide film 17 and silicon nitride film 18 between the buried silicon oxide film 20 and semiconductor substrate 10. Etching can be suppressed by the above-described film thicknesses because etchant is difficult to invade.

As described above, the preliminary polishing for finish polishing is performed by physical polishing before the main polishing for finish polishing. It is therefore possible to surely remove additive even if it is attached to the wafer surface. It is possible to remove a silicon oxide film on the whole surface of an even large diameter wafer.

Thereafter, a semiconductor element such as a CMOS transistor is formed in an active region defined by STI.

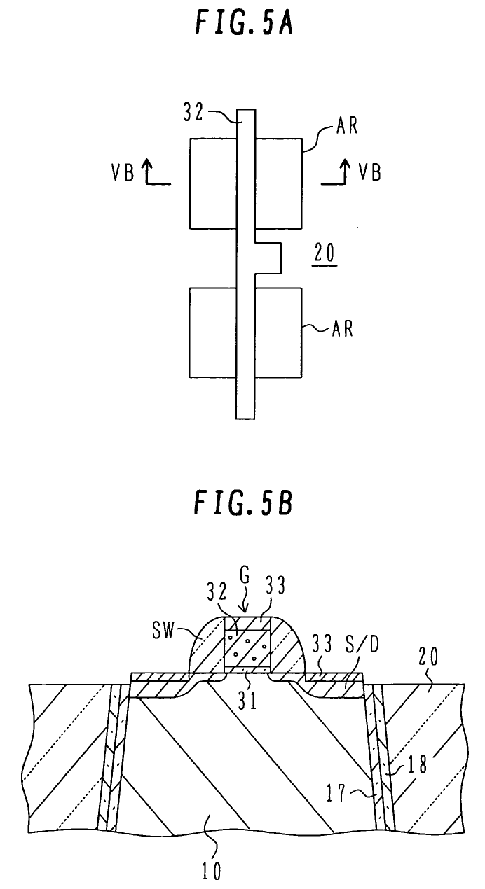

FIGS. 5A and 5B show an example of the structure of a CMOS transistor.

FIG. 5A is a plan view showing active regions AR defined by an element isolation region 20 and a shape of a gate electrode 32 formed above a silicon substrate. STI forms the element isolation region 20 and defines the active regions. In FIG. 5A, a CMOS inverter is formed in two active regions AR. FIG. 5A shows the state before side wall spacers are formed.

FIG. 5B is a cross sectional view taken along line VB-VB shown in FIG. 5A. A silicon oxide film liner 17 and a silicon nitride film liner 18 cover the inner surface of a trench and a silicon oxide film 20 is buried in the trench. In order to remove an unnecessary region of the silicon oxide film 20, polishing is performed including the above-described main polishing, preliminary polishing for finish polishing, and main polishing for finish polishing. A gate insulating film 31 of silicon oxynitride and a gate electrode 32 of polysilicon are formed traversing a p-type active region, and n-type impurity ions are implanted at a low concentration into the substrate on both sides of the gate electrode to form LDD regions. Side wall spacers SW are formed on the side walls of the gate electrode, and n-type impurity ions are implanted at a high concentration into the substrate to form high impurity concentration source/drain regions S/D. The other active region AR is an n-type, and p-type impurity ions are implanted. After ion implantation, for example, a Co film is deposited and a silicidation process is performed to form a silicide film 33 on the silicon surface. In this manner, a CMOS transistor is formed. Thereafter, interlayer insulating films and wirings are formed to complete a semiconductor device.

Since the insulating film can be removed from the whole wafer surface without partially leaving it, semiconductor chips can be formed on the whole wafer surface with good yield.

It has been found that a new problem occurs in the following process. After a trench is formed in a silicon substrate, a USG film is deposited by HDP-CVD, an unnecessary region of the USG film is removed by CMP using abrasive containing cerium dioxide abrasive grains to form STI, a PSG film is deposited by HDP-CVD after a gate electrode is formed, and the PSG film is planarized by using abrasive containing cerium dioxide abrasive grains.

In the following, description will be made on experiments made by the present inventor to study this problem.

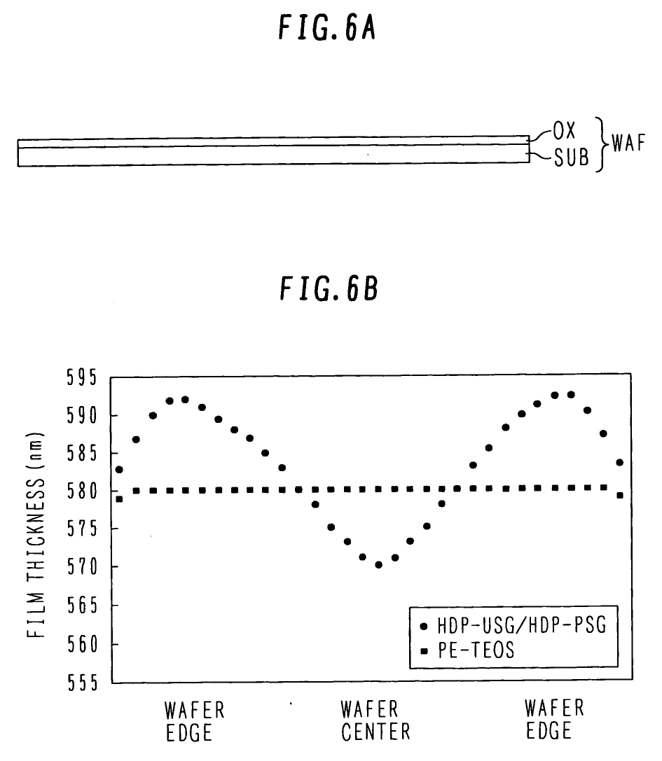

As shown in FIG. 6A, a wafer WAF was formed by forming a silicon oxide film OX on a silicon substrate SUB. Three samples of silicon oxide films OX were formed including a sample depositing a USG film HDP-USG by HDP-CVD, a sample depositing a PSG film HDP-PSG by HDP-CVD and a sample depositing a TEOS oxide film by PE-CVD using tetraetoxysilane (TEOS) as silicon source which is used as an interlayer insulating film and the like.

FIG. 6B is a graph showing measurement results of thickness distributions in wafers of three samples of silicon oxide films. The film thickness distribution of a sample PE-TEOS having the TEOS oxide film formed by PE-CVD has a value of about 580 nm in generally the whole wafer area and very high uniformity. The film thickness distributions of two samples HDP-USG and HDP-PSG having the silicon oxide films formed by HDP-CVD have almost the same variation at a wafer level. The thickness is as thin as about 570 nm in the wafer central area, gradually increases in the area outside the central area to take a maximum value of about 592 nm, and then becomes 585 nm or thinner toward the wafer peripheral area, indicating generally an M-character shaped distribution.

This M-character shaped distribution changes broadly and gently at a wafer level and does not change locally. It can be anticipated that although a local thickness change can be flattened by CMP, a gentle thickness change in a large area cannot be flattened by CMP.

A chip formed in the wafer central area has a thin interlayer insulating film, whereas a chip formed in the wafer peripheral area has a thick interlayer insulating film. When a contact hole is formed through the interlayer insulating film by etching, over-etch is increases in the thin central area because the contact hole is also formed through the thick interlayer insulating film in the peripheral area. A chip formed in the central area has a shorter conductive plug buried in the contact hole and a low contact resistance, whereas a chip formed in the peripheral area has a longer conductive plug and a high contact resistance. In order to improve the reliability of processes and products, it is desired to suppress a thickness variation at a wafer level as much as possible. Next, three types of samples were polished by the CMP system having the structure shown in FIGS. 1A to 1D and using slurry containing ceria abrasive grains and interfacial active agent.

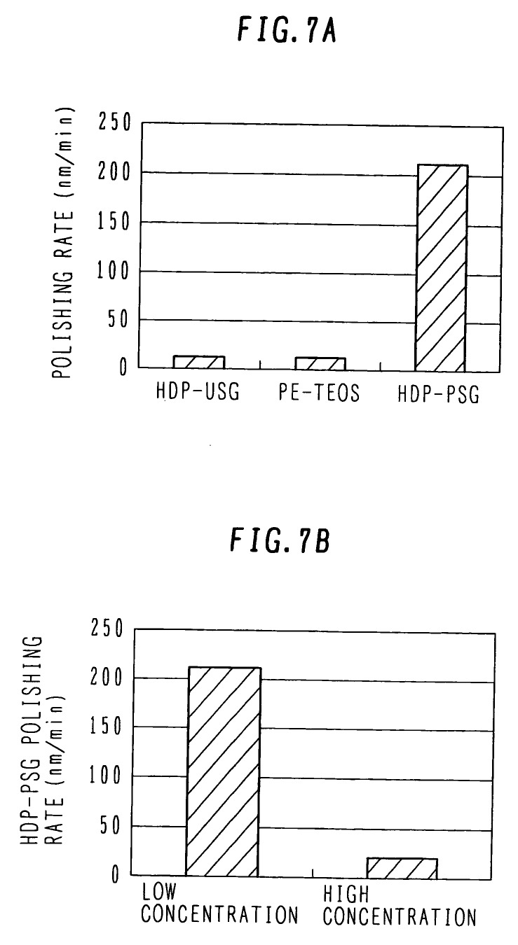

FIG. 7A shows polishing rates when three types of samples were subjected to CMP for one minute by using the same slurry. The ordinate represents a polishing rate in the unit of nm/min. The polishing rate was calculated by measuring the film thicknesses before and after polishing and by dividing a film thickness reduction amount by a polishing time. The polishing conditions were:

a polishing head pressure: 200 g weight/cm²,

a rotation speed of the polishing head: 100 rpm,

a rotation speed of the polishing table: 100 rpm, and

a supply amount of ceria slurry: 0.2 l/min.

A polishing pad of Model Number IC1400 of a K trench type manufactured by Nitta Haas Incorporated was used, and ceria slurry of Model Number MICROPLANAR STI2100 RA9 manufactured by Dupont Air Products NanoMaterials L.L.C. was used. Film thicknesses were measured with a film thickness measuring apparatus ASET-F5x manufactured by KLA-Tencor Corporation.

The polishing rates of the HDP-USG film and PE-TEOS film were both low 12 nm/min and 14 nm/min, respectively and polishing progresses hardly. This is characteristic to polishing a flat film with ceria slurry containing polyacrylate ammonium salt. It can be understood that an auto stop function is enabled. The polishing rate of the HDP-PSG film has an average of 210 nm/min which is fairly high as compared to 12 nm/min and 14 nm/min. It can be understood that the auto stop function is not enabled.

FIG. 7B shows polishing rates of the HDP-PSG film when an amount of polyacrylate ammonium salt contained in ceria slurry is changed. A left low concentration is the same as that of FIG. 7A, and a right high concentration is set by increasing the amount of polyacrylate ammonium salt by about ten times. As the amount of polyacrylate ammonium salt is increased by about ten times, the auto stop function is enabled also for the HDP-PSG film.

It can be understood from the results shown in FIGS. 7A and 7B that if the HDP-USG film and HDP-PSG are to be subjected to CMP with ceria slurry containing polyacrylate ammonium salt, an amount of polyacrylate ammonium salt is required to be changed greatly. If an STI burying oxide film is made of an HDP-USG film, and an interlayer insulating film burying gate electrodes is made of an HDP-PSG film, different CMPs are required to be performed. If one polishing system is used for one type of CMP, it is necessary to use two polishing systems for two types of CMPs.

The polishing rate of the PE-TEOS film is not different at all from that of the HDP-USG film. If the HDP-USG film and PE-TEOS film are to be subjected to CMP, CMP can be performed under the same conditions by using the same type of ceria slurry. However, the PE-TEOS film has lower burying performance and cannot be used as the interlayer insulating film burying gate electrodes.

The present inventor has considered that the interlayer insulating film burying gate electrodes is to be made of a lamination of an HDP-PSG film and a PE-TEOS film. The gate electrode is buried with the HDP-PSG film and the PE-TEOS film is stacked on the HDP-PSG film and polished.

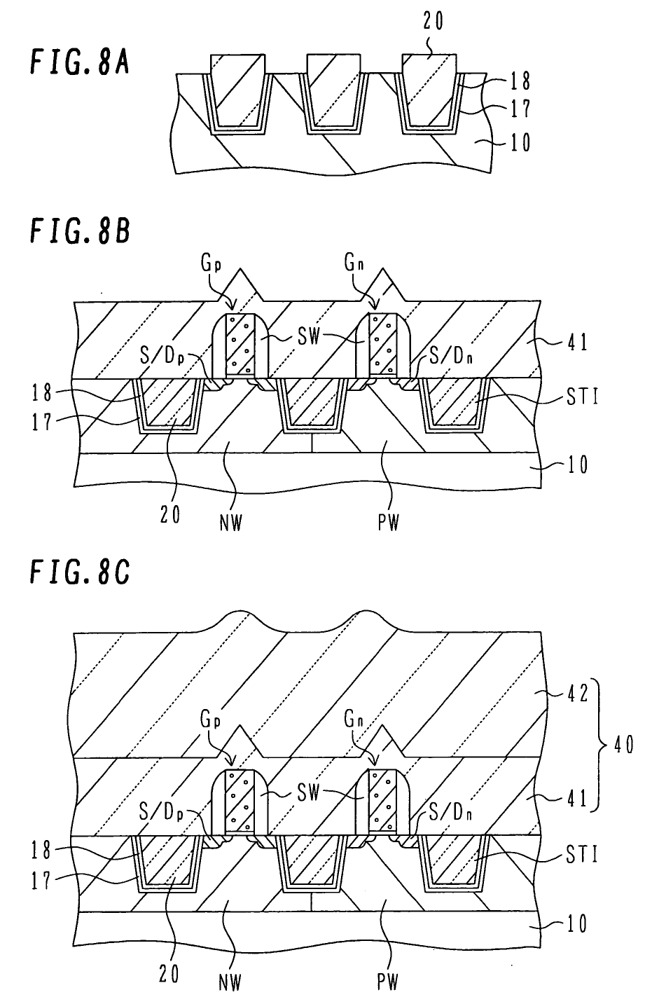

FIGS. 8A to 8C are partial cross sectional views of a semiconductor wafer illustrating a semiconductor device manufacture method according to another embodiment of the invention.

FIG. 8A shows the state shown in FIG. 3E. STI 20 is formed in a silicon substrate 10 by the processes similar to those shown in FIGS. 3A to 3E, STI defining active region.

As shown in FIG. 8B, on the silicon substrate formed with STI, resist masks are formed and impurity ions are implanted into the substrate to form an n-type well NW for a p-channel transistor and a p-type well PW for an n-channel transistor. Thereafter, the surface of an active region defined by STI is thermally oxidized to form a silicon oxide film, and a nitrogen process is executed to introduce nitrogen and form a silicon oxynitride film. On the silicon oxynitride film, a polysilicon film having a thickness of 100 to 200 nm, e.g., 180 nm is deposited by thermal CVD and patterned by using a resist pattern. An insulated gate electrode is therefore formed.

Shallow extensions are formed by implanting p-type impurity ions into a p-channel transistor region and n-type impurity ions into an n-channel transistor region at a low acceleration energy and a low concentration. After side walls SW of silicon oxide or the like are formed, low resistance source/drain regions S/Dₚ and S/Dₙ are formed by implanting p-type impurity ions into the p-channel transistor region and n-type impurity ions into the n-channel transistor region at a high concentration. A CMOS structure is therefore formed.

A PSG film 41 having a thickness thicker than the gate electrode, e.g., 200 nm, is deposited by HDP-CVD, burying the space between the gate electrodes and covering the gate electrodes. Since not PE-CVD but HDP-CVD is used, the burying performance is good and the space between the gate electrodes can be fully buried. The PSG film 41 has an irregular surface in conformity with the gate electrodes.

As shown in FIG. 8C, on the PSG film 41, a TEOS oxide film 42 is deposited to a thickness of, for example, 250 nm by PE-CVD. Since the surface of the HDP-PSG film 41 relaxes the radiuses of curvature of the underlying surface and aspect ratios, even PE-CVD having poor burying performance poses no problem regarding the burying performance. An interlayer insulating film 40 is constituted of the HDP-PSG film 41 and PE-TEOS film 42. As a comparative example, a sample having an interlayer insulating film 40 of a single HDP-PSG film was formed. The film thickness distributions of the interlayer insulating films above wafers were measured.

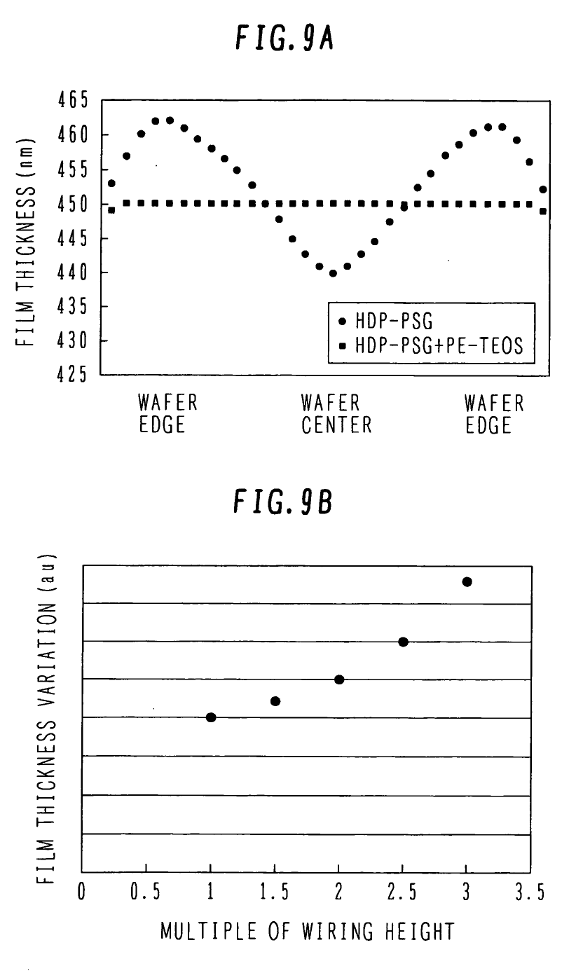

FIG. 9A is a graph showing the measurement results of the film thickness distributions. The film thickness distribution of the sample having the interlayer insulating film 40 of a single HDP-PSG film showed an M-character shaped distribution similar to that shown in FIG. 1B. The thickness was about 440 nm in a wafer central area, gradually increased in the area outside the central area to take a maximum value of about 462 nm, and then became about 453 nm toward the wafer peripheral area.

The film thickness distribution of the sample having the interlayer insulating film 40 of the lamination of the HDP-PSG film 41 and PE-TEOS film 42 shows almost a flat and stable value of about 450 nm in generally the whole wafer area. Although the reason is unknown, a flat surface was obtained by stacking the HDP-CVD film and PE-CVD film. The film thickness distribution of the interlayer insulating film 40 was studied by changing the thickness of the lower interlayer insulating film 41.

FIG. 9B is a graph showing the measurement results of the film thickness distributions. By using a thickness of the wiring (gate electrode) as a reference, a PSG film 41 was deposited by HDP-PSG to a thickness equal to or higher than the wiring height, and a TEOS oxide film was deposited on the PSG film 41 by PE-CVD. The ordinate represents a ratio of an HDP-PSG film thickness to the wiring height. The ordinate represents a film thickness variation in an arbitrary unit. In the area having a multiple of 2.5 or larger relative to the wiring height, the thickness variation tends to increase generally in proportion with the multiple. In the area having a multiple lower than 2, as the multiple lowers, the variation becomes smaller. In order to suppress the film thickness variation, it is considered preferable to form the HDP-PSG film having a thickness two times the wiring height or thinner or more preferably 1.5 times the wiring height or thinner.

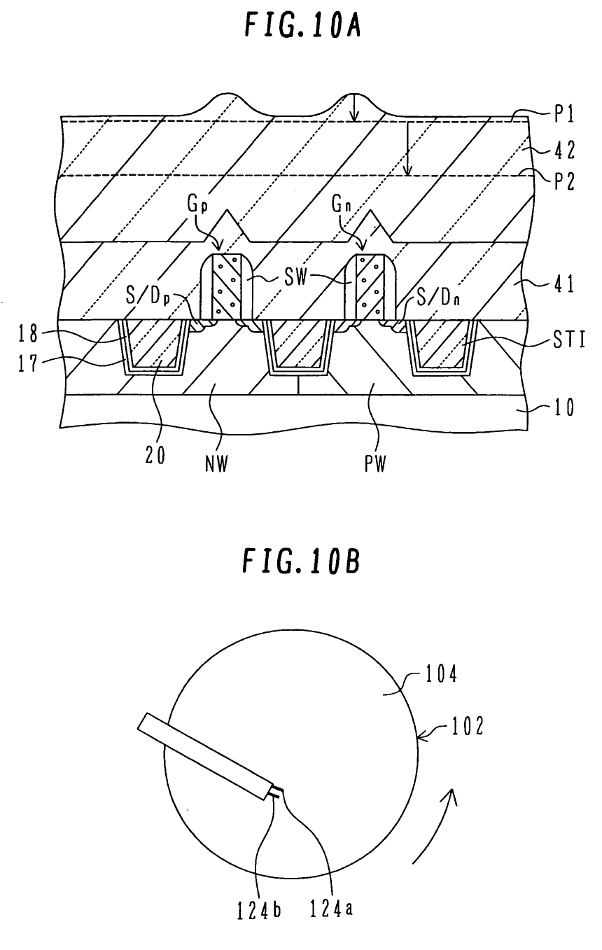

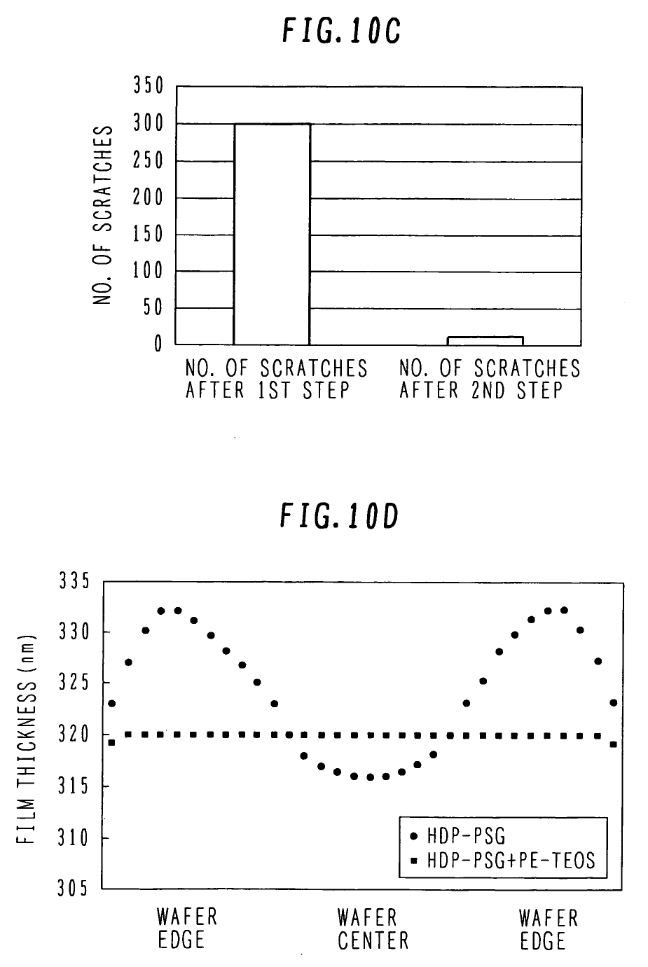

As shown in FIG. 10A, an interlayer insulating film 40 made of a lamination of an HDP-PSG film 41 and a PE-TEOS film 42 is polished by two steps. First, first step polishing is performed until an irregular surface of the interlayer insulating film 40 is removed. This polishing stops at a surface P1 shown in FIG. 10A. This polishing is performed by CMP which enables the auto stop function. The specific polishing conditions were set as in the following:

a polishing head pressure: 200 g weight/cm²,

a rotation speed of the polishing head: 100 rpm,

a rotation speed of the polishing table: 100 rpm, and

a supply amount of ceria slurry: 0.2 l/min.

A polishing pad of Model Number IC1400 of a K trench type manufactured by Nitta Haas Incorporated was used, and ceria slurry of Model Number MICROPLANAR STI2100 RA9 manufactured by Dupont Air Products NanoMaterials L.L.C. was used. A polishing time was 100 seconds.

The polishing consumes the film and forms scratches on a polished surface. As the auto stop function is enabled, consumption of the polished surface rapidly lowers. However, the number of scratches on the polished surface hardly changes. If the polished surface is consumed, scratches once formed are also consumed. However, if the polished surface is not consumed, scratches are successively accumulated.

Second polishing reduces scratches under the conditions of a certain polishing rate by relaxing the auto stop function. In order to relax the auto stop performance, the polishing was performed to a surface P2 by reducing a supply amount of ceria slurry and supplying pure water. The specific polishing conditions were set as in the following:

a polishing head pressure: 200 g weight/cm²,

a rotation speed of the polishing head: 100 rpm,

a rotation speed of the polishing table: 100 rpm,

a supply amount of ceria slurry: 0.1 l/min, and

a supply amount of pure water: 0.35 l/min.

A polishing pad of Model Number IC1400 of a K trench type manufactured by Nitta Haas Incorporated was used, and ceria slurry of Model Number MICROPLANAR STI2100 RA9 manufactured by Dupont Air Products NanoMaterials L.L.C. was used. This ceria slurry is the same kind as that used at the first step. The ceria slurry was diluted on the polishing table. In this case, cost is not more expensive than using already diluted slurry. A polishing rate of the second step was 100 nm/min.

As shown in FIG. 10B, the nozzle 124b for supplying pure water is disposed remoter from the center of the polishing table than the nozzle 124a for supplying ceria slurry.

FIG. 10C is a graph showing the numbers of scratches after the first and second steps. A left bar indicates the number of scratches after the first step polishing. A fairly large number of scratches, 300 scratches, are formed. A right bar indicates the number of scratches after the second step polishing. Although the number of scratches was about 300 after the first step, the number of scratches after the second step was reduced considerably to about 10 scratches.

FIG. 10D is a graph showing the film thickness distributions after the polishing. FIG. 10D also shows a film thickness distribution of a comparative sample (an interlayer insulating film of a single PSG layer formed by HDP-CVD). The film thickness distribution of the comparative sample is about 316 nm in a wafer central area, gradually increases in the area outside the central area to take a maximum value of about 332 nm, and then becomes about 323 nm toward the wafer peripheral area. The M-character shaped distribution remains. The interlayer insulating film of the embodiment has a stable film thickness of about 320 nm in generally the whole wafer area. It can be seen that the lamination interlayer insulating film of the embodiment prevents a thickness variation in the whole wafer area. CMP for the interlayer insulating film burying the gate electrodes can be performed properly by using ceria slurry of the same kind as that used for CMP of STI.

A pure water washing process may be inserted between the first step CMP and the second step CMP. A physical polishing process may be inserted if necessary. If the physical polishing process is inserted, it is preferable to perform pure water washing thereafter. In the above description, the lower interlayer insulating film is deposited to a depth equal to or larger than the wiring (gate electrode) height. It is sufficient if the thickness of the lower interlayer insulating film can relax the cubic structure (steps, radiuses of curvature, etc) of the underlying layers not easy to be buried. The surface of the lower interlayer insulating film is not necessarily required to be higher than the wiring surface.

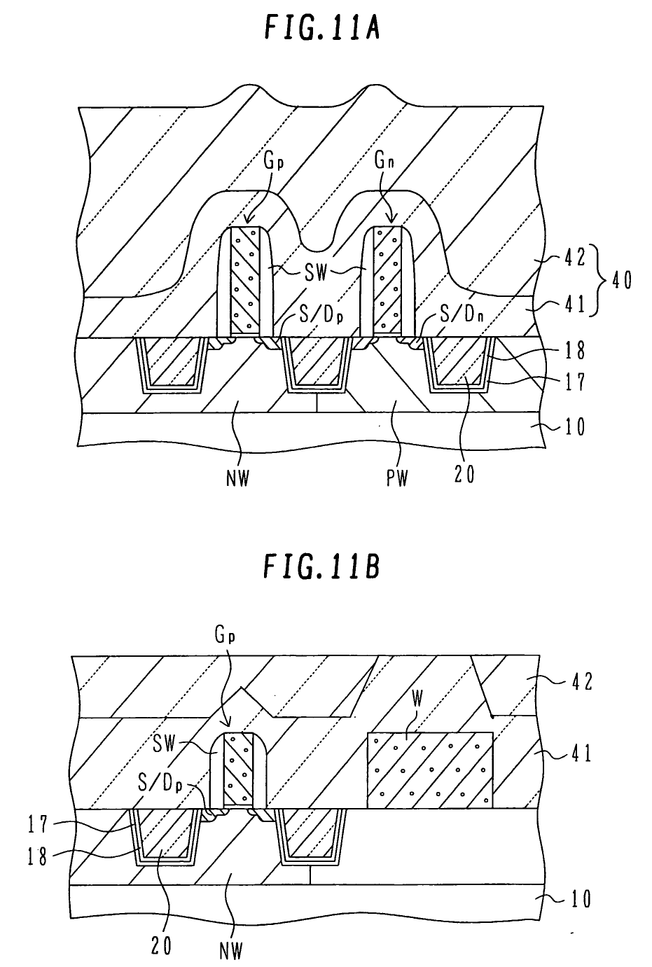

FIG. 11A shows a modification of the embodiment. A thickness of a PSG lower interlayer insulating film 41 deposited by HDP-CVD is set smaller than a height of a gate electrode G. The deposited lower interlayer insulating film has an uneven surface and its concave region is lower than the surface (top surface) of the gate electrode. Although an HDP-PSG film have good burying performance, uniformity of a film thickness is not guaranteed. It is expected that uniformity of film thickness distributions of the whole lamination interlayer insulating film 40 is stably guaranteed if the underlying cubic structure is relaxed by limiting the thickness of the HDP-PSG lower interlayer insulating film 41.

FIG. 11B shows another modification. If a wiring W such as a local interconnect is formed by using the same layer as a gate wiring G, a height of a lower interlayer insulating film 41 on the wiring W may become higher than that of another region. In this higher region, a portion of the lower interlayer insulating film 41 may be exposed by the first step CMP. Even if the lower interlayer insulating film is exposed by the first step CMP, this exposure can be permitted unless practical problems occur.

In the above-described embodiment, although the lower interlayer insulating film is made of an HDP-PSG film, it may be made of an HDP-USG film. An insulating film having good burying performance is formed by HDP-CVD and an oxide film such as a TEOS oxide film to be polished is formed on the insulating film by PE-CVD. If a thickness of the HDP-CVD insulating film is limited and a PE-CVD film having good planarization is formed on the HDP-CVD insulating film, it is expected a lamination interlayer insulating film having good planarization can be formed. If only uniformity of film thicknesses in the whole wafer area is aimed, the material of the upper interlayer insulating film is not limited to TEOS oxide and a film forming method is not limited to PE-CVD if the method can form a film having good uniformity of film thicknesses. The wiring is not limited to that made of the same layer as that of the gate electrode.

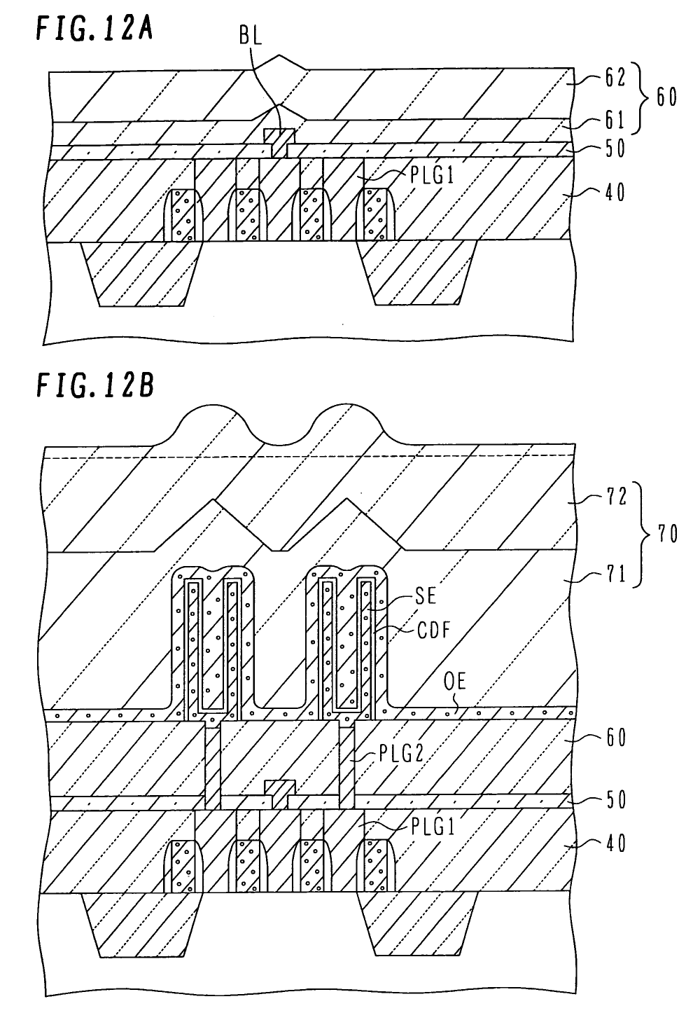

FIGS. 12A and 12B show an example of a wiring different from a gate wiring.

FIGS. 12A and 12B illustrate a manufacture method for a dynamic random access memory (DRAM). As shown in FIG. 12A, n-channel MOS transistors are formed in a memory cell area of a semiconductor substrate by processes similar to those shown in FIGS. 8A to 8C. In FIGS. 12A and 12B, two n-channel MOS transistors share a center source/drain region and memory capacitors are connected to opposite source/drain regions. After MOS transistors are formed, an interlayer insulating film 40 is formed burying the gate electrodes.

After the surface of the interlayer insulating film 40 is planarized by CMP, contact holes reaching the source/drain regions are formed by photolithography and etching, and polysilicon or the like is deposited in the contact holes to form conductive plugs PLG1. After the unnecessary conductive film on the surface is removed by CMP, a silicon oxide film is deposited to form an interlayer insulating film 50.

A contact hole is formed through the interlayer insulating film 50, reaching the conductive plug PLG1 shown in the central area in FIG. 12A. A wiring layer of aluminum alloy or the like is deposited by sputtering and patterned by photolithography and etching to form a bit line BL.

An HDP-PSG film 61 and a PE-TEOS film 62 are formed covering the bit line BL. The surface is planarized by two-step CMP similar to that described above to form an interlayer insulating film 60.

As shown in FIG. 12B, contact holes are formed through the interlayer insulating films 60 and 50, reaching the conductive plugs PLG1 on opposite sides, and conductive plugs PLG2 are buried in the contact holes. A storage electrode SE of polysilicon or the like is formed being connected to the conductive plug PLG2. A capacitor dielectric film CDF made of a thermally oxidized silicon oxide film or the like and an opposing electrode OE of polysilicon or the like are formed. Any known method may be used as a manufacture method for a DRAM capacitor. An HDP-PSG film 71 and a PE-TEOS film 72 are deposited burying the capacitors, to form an interlayer insulating film 70. The surface of the interlayer insulating film 70 has an irregular surface, being reflected by the structure of the underlying capacitors. The surface of the interlayer insulating film 70 is planarized by two-step CMP similar to that described above.

As above, if a wiring structure has an irregular surface, steps, radiuses of curvature and the like are first relaxed by HDP providing excellent burying performance, and then a silicon oxide film is deposited by PE-CVD providing good uniformity of film thicknesses and stable CMP, to thereby form a good quality interlayer insulating film. This interlayer insulating film is planarized by two-step CMP to form an interlayer insulating film having a uniform thickness and a flat surface.

The present invention has been described in connection with the preferred embodiments. The invention is not limited only to the above embodiments. For example, in addition to polyacrylate ammonium salt, polyvinylpyrrolidone or the like may be used as additive of ceria based abrasive. In addition to silica based abrasive, zirconia based abrasive or the like may be used for physical polishing. A film to be polished is not limited to a silicon oxide film, but other films such as a silicon oxynitride film may be used. In summary, a lower insulating film is formed by HDP-CVD providing good burying performance and an upper insulating film having good uniformity (thickness uniformity) is formed on the lower insulating film. It will be apparent to those skilled in the art that other various modifications, improvements, combinations, and the like can be made.

What are claimed are:

1. A manufacture method for a semiconductor device, comprising the steps of:
(a) while supplying first abrasive to a polishing table provided with a polishing pad, polishing a surface of a film formed on a semiconductor substrate supported by a polishing head, by using said polishing pad, until the surface of said film is planarized, said first abrasive containing cerium dioxide abrasive grains and additive of interfacial active agent;
(b) after said step (a), polishing the surface of said film by using second abrasive having a physically polishing function; and
(c) after said step (b), polishing the surface of said film by using third abrasive containing cerium dioxide abrasive grains, additive of interfacial active agent, and diluent.

2. The manufacture method for a semiconductor device according to claim 1, wherein said second abrasive contains silica or zirconia as polishing abrasive grains.

3. The manufacture method for a semiconductor device according to claim 1, wherein said diluent is water, and said third abrasive is formed by mixing said first abrasive and water on said polishing table.

4. The manufacture method for a semiconductor device according to claim 1, wherein after at least one of said step (a) and said step (b), water is supplied to said polishing table to wash out the abrasive.

5. The manufacture method for a semiconductor device according to claim 1, wherein said steps (a), (b) and (c) are executed on a same polishing table.

6. The manufacture method for a semiconductor device according to claim 1, wherein said steps (a), (b) and (c) are executed on two or three polishing tables.

7. The manufacture method for a semiconductor device according to claim 1, wherein in at least one of said steps (a) and (c), an end point of polishing is detected from a variation in rotation torque of said polishing table or said polishing head.

8. The manufacture method for a semiconductor device according to claim 1, wherein:
said semiconductor substrate is a silicon substrate;
the manufacture method further comprises before said step (a), steps of:
(x) stacking a buffer silicon oxide film and a silicon nitride film on a surface of said silicon substrate and forming an etching mask by patterning at least said silicon nitride film;
(y) forming a trench in said silicon substrate by using said etching mask, said trench isolating active regions; and
(z) depositing an insulating film on said silicon substrate and burying said trench with said insulating film; and
said step (c) performs polishing while using said etching mask as a polishing stopper.

9. The manufacture method for a semiconductor device according to claim 8, wherein said step (z) thermally oxidizes a surface of said trench before said insulating film is deposited, to form a silicon oxide film, then deposits a silicon nitride film, and thereafter deposits a silicon oxide film by high density plasma chemical vapor deposition.

10. The manufacture method for a semiconductor device according to claim 8, wherein after said step (c), said silicon nitride film and said buffer silicon oxide film are etched and thereafter MOS transistors are formed in said active regions.

11. A manufacture method for a semiconductor device, comprising the steps of:
(a) forming wirings above a semiconductor substrate;
(b) after said step (a), depositing a first insulating film by high density plasma (HDP) chemical vapor deposition (CVD), said first insulating film burying said wirings;
(c) after said step (b), depositing a second insulating film above said first insulating film by a deposition method different from HDP-CVD; and
(d) after said step (c), planarizing said second insulating film by chemical mechanical polishing using abrasive containing cerium dioxide abrasive grains.

12. The manufacture method for a semiconductor device according to claim 11, wherein said step (d) includes a first polishing step using first slurry whose polishing rate lowers greatly when an uneven surface is planarized and a second polishing step using second slurry whose polishing rate is faster than a polishing rate of said first polishing step.

13. The manufacture method for a semiconductor device according to claim 12, wherein said second slurry is said first slurry diluted with water.

14. The manufacture method for a semiconductor device according to claim 13, wherein said second slurry is formed by mixing said first slurry with water on a polishing table.

15. The manufacture method for a semiconductor device according to claim 11, wherein the deposition method different from HDP-CVD for depositing said second insulating film is plasma enhanced (PE) CVD.

16. The manufacture method for a semiconductor device according to claim 11, wherein said first insulating film is a phosphosilicate glass (PSG) film or a borophosphosilicate glass (BPSG) film.

17. The manufacture method for a semiconductor device according to claim 11, wherein:
said semiconductor substrate is a silicon substrate; and
the manufacture method further comprises, before said step (a), the steps of:
(x) forming a trench in said silicon substrate, said trench isolating active regions;
(y) depositing an undoped silicate glass (USG) film on said silicon substrate by HDP-CVD, said USG film burying said trench; and
(z) removing said USG film outside said trench by chemical mechanical polishing using abrasive containing cerium dioxide abrasive grains.

18. The manufacture method for a semiconductor device according to claim 17, wherein said step (c) forms said second insulating film by PE-CVD using tetraetoxysilane (TEOS) as silicon source, and the abrasive used by said step (z) and said step (c) has a same composition.

19. A semiconductor device comprising:
a silicon substrate;
a shallow trench isolation (STI) including a trench formed in said silicon substrate, defining active regions, and an undoped silicate glass film buried in said trench;
a gate insulating film formed on said active region;
a gate electrode formed above said gate insulating film;
a lower insulating film of phosphosilicate glass (PSG) or borophosphosilicate glass (BPSG) having an uneven surface with a concave portion and formed above said silicon substrate, said lower insulating film covering said gate electrode; and
an upper insulating film of TEOS silicon oxide formed above said lower insulating film and having a planarized surface.

20. The semiconductor device according to claim 19, wherein said concave portion of said lower insulating film is lower than a surface of said gate electrode.
